(19) United States
(12) Patent Application Publication
(10) Pub. No.: US 2025/0324879 A1
(43) Pub. Date: Oct. 16, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Xiaoguang ZHU, Wuhan, Hubei (CN); Tao CHEN, Wuhan, Hubei (CN); Zhiqiao LIU, Wuhan, Hubei (CN); Guo CHENG, Wuhan, Hubei (CN); Zhuo ZHANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/870,442

(22) PCT Filed: Jun. 29, 2023
(86) PCT No.: PCT/CN2023/104272

§ 371 Date: Nov. 28, 2024

(30) Foreign Application Priority Data
Sep. 15, 2022 (CN) 202211122994.5

(51) Int. Cl. H10K 59/35

(52) U.S. Cl. CPC H10K 59/353

(57) ABSTRACT

Embodiments of the present disclosure provides a display panel and a display device. Any two opposite sides of a virtual quadrilateral are not parallel. In the virtual quadrilateral, lengths of two sides adjacent to a first sub-pixel located at a vertex corner of a virtual rectangle are not equal. The third sub-pixel is disposed within the virtual quadrilateral. Distances between a centre of the third sub-pixel and centres of two first sub-pixels corresponding to the virtual quadrilateral are equal, and the centre of the third sub-pixel is not on a line connecting the centres of the two first sub-pixels corresponding to the virtual quadrilateral.

### TECHNICAL FIELD

The present application relates to the field of display technology, and in particular, to a display panel and a display device including the display panel.

### BACKGROUND

Organic light-emitting diode (OLED) display panels emit light autonomously through an organic layer. Since the OLED display panels do not require a backlight, they have faster response, larger viewing angles, higher contrast ratios, and characteristics such as smaller weight, lower power consumption, which makes them recognized as the most promising flat panel display technology.

Currently, in high-resolution OLED display panels, the organic layer includes an electronic layer, an organic light-emitting layer, and a hole transfer layer. The electronic layer and the hole transfer layer are both prepared over the entire substrate, and there are at least a part of pixels having a small spacing therebetween, allowing the electrons to easily migrate through the electronic layer, resulting in an electrical crosstalk between adjacent pixels. Moreover, in the high-resolution OLED display panels, due to the small spacing between adjacent pixels, the space for manufacturing support columns, used to support a MASK fixture (for evaporation of organic light-emitting materials), is limited, which thus affects a support effect of the support columns.

### SUMMARY

Embodiments of the present disclosure provide a display panel and a display device, which may reduce the probability of the electrical crosstalk occurring between adjacent sub-pixels and improve a display effect of the display panel. In addition, the space for manufacturing the support columns may be increased and the support effect of the support columns may be enhanced.

Some embodiments of the present disclosure provide a display panel, including a plurality of first sub-pixels, a plurality of second sub-pixels, and a plurality of third sub-pixels.

Each first sub-pixel is either arranged at a corresponding one of four vertex corners of or arranged within a corresponding virtual rectangle of one or more virtual rectangles.

Each second sub-pixel is arranged on a corresponding one of four sides of the virtual rectangle.

In each virtual rectangle, each first sub-pixel located at the corresponding vertex corner of the virtual rectangle, two of the plurality of second sub-pixels adjacent to the first sub-pixel, and the first sub-pixel located within the virtual rectangle form a virtual quadrilateral, such that a plurality of virtual quadrilaterals are formed in the virtual rectangle. Any two opposite sides of each virtual quadrilateral are not parallel. In each virtual quadrilateral, lengths of two sides of the virtual quadrilateral adjacent to the first sub-pixel located at the vertex corner of the virtual rectangle are not equal.

Each third sub-pixel is disposed within a corresponding one of the plurality of virtual quadrilateral; in each virtual quadrilateral, distances between a centre of the third sub-pixel and centres of the two first sub-pixels corresponding to the virtual quadrilateral are equal, and the centre of the third sub-pixel is not on a line connecting the centres of the two first sub-pixels corresponding to the virtual quadrilateral.

In some embodiments of the present disclosure, in each virtual quadrilateral, the centre of the third sub-pixel is located on a mid-perpendicular line of a line connecting centres of the two second sub-pixels corresponding to the virtual quadrilateral.

In some embodiments of the present disclosure, on at least one side of each virtual rectangle, a first distance from a centre of the second sub-pixel to a centre of one of the first sub-pixels adjacent to the second sub-pixel is smaller than a second distance from the centre of the second sub-pixel to a centre of another of the first sub-pixels adjacent to the second sub-pixel.

In some embodiments of the present disclosure, the display panel further includes:
a plurality of support columns, wherein each support column is disposed on a corresponding side of the virtual rectangle and is between one of the plurality of first sub-pixels and one of the plurality of second sub-pixels that are on the side of the virtual rectangle and adjacent to each other, and a distance from a centre of the first sub-pixel adjacent to the support column to a centre of the second sub-pixel adjacent to the support column is the second distance.

In some embodiments of the present disclosure, each virtual rectangle includes a first side, a second side, a third side, and a fourth side, the first side is arranged opposite to the second side, and the third side is arranged opposite to the fourth side.

A line connecting centres of two of the plurality of second sub-pixels respectively located on the first side and the second side is not parallel to the third side.

A line connecting centres of other two of the plurality of second sub-pixels respectively located on the third side and the fourth side is not parallel to the first side.

In some embodiments of the present disclosure, in the virtual rectangle, a centre of one of the second sub-pixel located on the first side does not overlap with a midpoint of the first side, a centre of the second sub-pixel located on the second side does not overlap with a midpoint of the second side, a centre of the second sub-pixel located on the third side does not overlap with a midpoint of the third side, and a centre of the second sub-pixel located on the fourth side does not overlap with a midpoint of the fourth side.

In some embodiments of the present disclosure, in the virtual rectangle, the centre of the second sub-pixel located on the first side and the centre of the second sub-pixel located on the second side are respectively located on opposite sides of a mid-perpendicular line of the first side.

The centre of the second sub-pixel located on the third side and the centre of the second sub-pixel located on the fourth side are respectively located on opposite sides of a mid-perpendicular line of the third side.

In some embodiments of the present disclosure, in the virtual rectangle, a distance from the centre of the second sub-pixel located on the first side to the midpoint of the first side, a distance from the centre of the second sub-pixel located on the second side to the midpoint of the second side, a distance from the centre of the second sub-pixel located on the third side to the midpoint of the third side, and a distance from the centre of the second sub-pixel located on the fourth side to the midpoint of the fourth side are equal.

In some embodiments of the present disclosure, in the virtual rectangle, a distance from a centre of the first sub-pixel within the virtual rectangle to the first side, a distance from the centre of the first sub-pixel within the virtual rectangle to the second side, a distance from the centre of the first sub-pixel within the virtual rectangle to the third side, and a distance from the centre of the first sub-pixel within the virtual rectangle to the fourth side are equal.

In some embodiments of the present disclosure, the display panel includes a plurality of repeating units. Each repeating unit includes four virtual rectangles, and the four virtual rectangles are arranged in an array along a first direction and a second direction, the first direction is a direction pointing from the first side to the second side, and the second direction is a direction pointing from the third side to the fourth side.

In each repeating unit, in any two adjacent virtual rectangles along the first direction, the first side of one of the two virtual rectangles and the second side of the other of the two virtual rectangles are both on a first virtual straight line, and the two virtual rectangles are arranged axially symmetrically with respect to the first virtual straight line.

In each repeating unit, in any two adjacent virtual rectangles along the second direction, the third side of one of the two virtual rectangles and the fourth side of the other of the two virtual rectangles are both located on a second virtual straight line, and the two virtual rectangles are arranged axially symmetrically with respect to the second virtual straight line.

In some embodiments of the present disclosure, in each virtual rectangle, lines connecting a centre of the first sub-pixel located within the virtual rectangle and centres of four of the plurality of second sub-pixels respectively located on the four sides of the virtual rectangle divide the virtual rectangle into four virtual quadrilaterals.

In some embodiments of the present disclosure, in any one of the virtual quadrilaterals, the first sub-pixel located within the virtual rectangle is adjacent to two of the plurality of second sub-pixels corresponding to the virtual quadrilateral, a line connecting the centre of the first sub-pixel located within the virtual rectangle and a centre of one of the two adjacent second sub-pixels and another line connecting the centre of the first sub-pixel located within the virtual rectangle and a centre of the other one of the two adjacent second sub-pixels form a first angle. The second sub-pixel on a side of the virtual rectangle is adjacent to two of the plurality of first sub-pixels, a line connecting a centre of the second sub-pixel on the side of the virtual rectangle and a centre of one of the two adjacent first sub-pixels and another line connecting the centre of the second sub-pixel on the side of the virtual rectangle and a centre of the other one of the two adjacent first sub-pixels form a second angle. An absolute value of a difference between the first angle and the second angle is greater than 0° and less than or equal to 20°.

According to the above objectives of the present disclosure, some embodiments of the present disclosure further provide a display device including a device body and a display panel, and the display panel and the device body are combined into one body.

The display panel includes a plurality of first sub-pixels, a plurality of second sub-pixels, and a plurality of third sub-pixels.

Each first sub-pixel is either arranged at a corresponding one of four vertex corners of or arranged within a corresponding virtual rectangle of one or more virtual rectangles.

Each second sub-pixel is arranged on a corresponding one of four sides of the virtual rectangle.

In each virtual rectangle, each first sub-pixel located at the corresponding vertex corner of the virtual rectangle, two of the plurality of second sub-pixels adjacent to the first sub-pixel, and the first sub-pixel located within the virtual rectangle form a virtual quadrilateral, such that a plurality of virtual quadrilaterals are formed in the virtual rectangle. Any two opposite sides of each virtual quadrilateral are not parallel. In each virtual quadrilateral, lengths of two sides adjacent to the first sub-pixel located at the vertex corner of the virtual rectangle are not equal.

Each third sub-pixel is disposed within a corresponding one of the plurality of virtual quadrilateral; in each virtual quadrilateral, distances between a centre of the third sub-pixel and centres of the two first sub-pixels corresponding to the virtual quadrilateral are equal, and the centre of the third sub-pixel is not on a line connecting the centres of the two first sub-pixels corresponding to the virtual quadrilateral.

In some embodiments of the present disclosure, in each virtual quadrilateral, the centre of the third sub-pixel is located on a mid-perpendicular line of a line connecting centres of the two second sub-pixels corresponding to the virtual quadrilateral.

In some embodiments of the present disclosure, on at least one side of each virtual rectangle, a first distance from a centre of the second sub-pixel to a centre of one of the first sub-pixels adjacent to the second sub-pixel is smaller than a second distance from the centre of the second sub-pixel to a centre of another of the first sub-pixels adjacent to the second sub-pixel.

In some embodiments of the present disclosure, the display panel further includes:
a plurality of support columns, wherein each support column is disposed on a corresponding side of the virtual rectangle and is between one of the plurality of first sub-pixels and one of the plurality of second sub-pixels that are on the side of the virtual rectangle and adjacent to each other, and a distance from a centre of the first sub-pixel adjacent to the support column to a centre of the second sub-pixel adjacent to the support column is the second distance.

In some embodiments of the present disclosure, each virtual rectangle includes a first side, a second side, a third side, and a fourth side, the first side is arranged opposite to the second side, and the third side is arranged opposite to the fourth side.

A line connecting centres of two of the plurality of second sub-pixels respectively located on the first side and the second side is not parallel to the third side.

A line connecting centres of other two of the plurality of second sub-pixels respectively located on the third side and the fourth side is not parallel to the first side.

In some embodiments of the present disclosure, in the virtual rectangle, a centre of one of the second sub-pixel located on the first side does not overlap with a midpoint of the first side, a centre of the second sub-pixel located on the second side does not overlap with a midpoint of the second side, a centre of the second sub-pixel located on the third side does not overlap with a midpoint of the third side, and a centre of the second sub-pixel located on the fourth side does not overlap with a midpoint of the fourth side.

In some embodiments of the present disclosure, in the virtual rectangle, the centre of the second sub-pixel located on the first side and the centre of the second sub-pixel located on the second side are respectively located on opposite sides of a mid-perpendicular line of the first side.

The centre of the second sub-pixel located on the third side and the centre of the second sub-pixel located on the fourth side are respectively located on opposite sides of a mid-perpendicular line of the third side.

In some embodiments of the present disclosure, in the virtual rectangle, a distance from the centre of the second sub-pixel located on the first side to the midpoint of the first side, a distance from the centre of the second sub-pixel located on the second side to the midpoint of the second side, a distance from the centre of the second sub-pixel located on the third side to the midpoint of the third side, and a distance from the centre of the second sub-pixel located on the fourth side to the midpoint of the fourth side are equal.

### BENEFICIAL EFFECTS

A display panel provided by the present disclosure includes the virtual rectangles, and each virtual rectangle includes the virtual quadrilaterals. In each virtual quadrilateral, the distances from the centre of the third sub-pixel to the centres of the two first sub-pixels are equal, and the centre of the third sub-pixel is not on the line connecting the centres of the two first sub-pixels. That is, compared to the arrangement where the centre of the third sub-pixel is on the line connecting the two first sub-pixels, in the present disclosure, the third sub-pixel located within the virtual quadrilateral is specifically designed so that the centre of the third sub-pixel is not on the line connecting the centres of the two first sub-pixels, which may increase the distance between the third sub-pixel and the two first sub-pixels and keep the distances between the third sub-pixel and the two first sub-pixels equal, thereby reducing the probability of an electrical crosstalk between the third sub-pixel and the two first sub-pixels and then improving the display effect. In addition, in each virtual quadrilateral of the display panel, the two sides adjacent to the first sub-pixel located at the vertex corner of the virtual rectangle are not equal, and the longer side thereof may be used for the arrangement of the support column, thereby increasing the manufacturing space for the support column to enhance the support effect of the support column and thereby preventing the mask from scratching the display panel.

### BRIEF DESCRIPTION OF THE DRAWINGS

The technical solutions and other beneficial effects of the present disclosure will be apparent through a detailed description of specific embodiments of the present disclosure in conjunction with the accompanying drawings.

FIG. 1 is a schematic diagram of a pixel arrangement structure corresponding to a virtual rectangle provided by some embodiments of the present disclosure.

FIG. 2 is a schematic diagram of a pixel arrangement structure corresponding to a repeating unit provided by some embodiments of the present disclosure.

### EMBODIMENTS OF THE INVENTION

The technical solutions in the embodiments of the present application will be clearly and completely described below with reference to the accompanying drawings in the embodiments of the present disclosure. Obviously, the described embodiments are only some of the embodiments of the present application, rather than all of the embodiments. Based on the embodiments in this disclosure, all other embodiments obtained by those skilled in the art without making creative efforts fall within the scope of protection of this disclosure.

The following disclosure provides many different embodiments or examples for implementing the various structures of the present disclosure. To simplify the disclosure of the present disclosure, the components and arrangements of specific examples are described below. Of course, they are merely examples and are not intended to limit the disclosure. Furthermore, the present disclosure may repeat reference numbers and/or reference letters in different examples, such repetition being for the purposes of simplicity and clarity and does not by itself indicate a relationship between the various embodiments and/or arrangements discussed. In addition, this disclosure provides examples of various specific processes and materials, but one of ordinary skill in the art will recognize the application of other processes and/or the use of other materials.

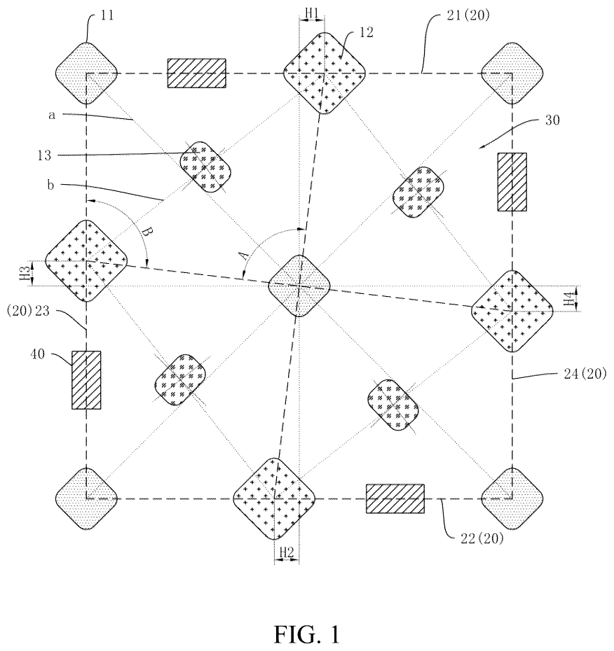

Embodiments of the present disclosure provide a display panel. Please refer to FIG. 1. The display panel includes a plurality of first sub-pixels 11, a plurality of second sub-pixels 12, and a plurality of third sub-pixels 13.

Each first sub-pixels 11 is arranged at a corresponding one of four vertex corners of a virtual rectangle 20 or within the virtual rectangle 20. Each second sub-pixel 12 is arranged on a corresponding one of four sides of the virtual rectangle 20. In one virtual rectangle 20, a first sub-pixel 11 at one vertex corner of the virtual rectangle, two second sub-pixels 12 adjacent to the first sub-pixel 11, and the first sub-pixel within the virtual rectangle form a virtual quadrilateral 30, so that a plurality of virtual quadrilaterals are formed in each virtual rectangle. Any two opposite sides of the virtual quadrilateral 30 are not parallel. In the virtual quadrilateral 30, lengths of two sides of the virtual quadrilateral 30 adjacent to the first sub-pixel 11 located at the vertex corner of the virtual rectangle 20 are not equal.

Further, each third sub-pixel 13 is disposed within one of the virtual quadrilaterals 30, distances between a centre of the third sub-pixel 13 and centres of the two first sub-pixels 11 corresponding to the virtual quadrilateral 30 are equal, and the centre of the third sub-pixel 13 is not on a line connecting the centres of the two first sub-pixels 11 corresponding to the virtual quadrilateral 30.

During an application process, the display panel provided by the embodiments of the present disclosure includes virtual rectangles 20, and each virtual rectangle 20 includes virtual quadrilaterals 30. In each virtual quadrilateral 30, the distances from the centre of the third sub-pixel 13 to the two sub-pixels 13 corresponding to the virtual quadrilateral 30 are same, and the centre of the third sub-pixel 13 is not on the line connecting the centres of the two first sub-pixels 11. That is, compared with the arrangement where the centre of the third sub-pixel 13 is on the line connecting the centres of the two first sub-pixels 11, in the present disclosure, a position of the third sub-pixel 13 within the virtual quadrilateral 30 is specifically designed, so that the centre of the third sub-pixel 13 is not on the line connecting the centres of the two first sub-pixels 11, which may increase a distance between the third sub-pixel 13 and each of the two first sub-pixels 11; besides, by keep the distances between the third sub-pixel 13 and the two first sub-pixels 11 equal, the probability of an electrical crosstalk occurring between the third sub-pixel 13 and the two first sub-pixels 13 may be reduced, which further improves a display effect. In addition, in the virtual quadrilateral 30 of the display panel, the two sides adjacent to the first sub-pixel 11 located at the vertex corner of the virtual rectangle 20 are not equal, and a longer side of the two sides may be used for the arrangement of a support column, thereby increasing manufacturing space of the support column, which enhances a support effect of the support column, and consequently prevents any mask from scratching the display panel.

Specifically, please continue to refer to FIG. 1. It should be noted that the virtual rectangle 20 and the virtual quadrilaterals 30 described in the embodiments of the present disclosure are configured for convenience of description. An actual display panel does not have such virtual rectangle 20 and virtual quadrilaterals 30.

In some embodiments of the present disclosure, please continue to refer to FIG. 1, the display panel includes a plurality of sub-pixels. The plurality of sub-pixels include a plurality of first sub-pixels 11, a plurality of second sub-pixels 12, and a plurality of third sub-pixels 13. The plurality of first sub-pixels 11, the plurality of second sub-pixels 12, and the plurality of third sub-pixels 13 are distributed in a display area of the display panel, and each sub-pixel emits light to realize a display function of the display panel.

Optionally, the first sub-pixels 11 may be red sub-pixels, the second sub-pixels 12 may be blue sub-pixels, and the third sub-pixels 13 may be green sub-pixels, wherein an area of each first sub-pixel 11 may be smaller than an area of each second sub-pixel 12 but greater than an area of each third sub-pixel 13. Further, a shape of each sub-pixel may be a circle, an ellipse, or other polygons. In some embodiments of the present disclosure, the shapes of the sub-pixels are rounded rectangles, which is an example for explanation, however are not limited thereto and may be selected according to actual needs.

In some embodiment of the present disclosure, in order to facilitate the description of the arrangement of the plurality of sub-pixels, a plurality of virtual rectangles 20 may be arranged in the display panel, and the plurality of sub-pixels are all distributed in the virtual rectangles 20.

Specifically, the first sub-pixels 11 are respectively disposed at four vertex corners and an inner point of each virtual rectangle 20, and the second sub-pixels 12 are disposed on four sides of each virtual rectangle 20. Each vertex corner of the virtual rectangle 20 is provided with one first sub-pixel 11, an additional one first sub-pixel 11 is provided in the virtual rectangle 20, and each side of the virtual rectangle 20 is provided with one second sub-pixel 12.

Lines connecting the centre of the first sub-pixel 11 located within the virtual rectangle 20 and the centres of the four second sub-pixels 12 respectively located on the four sides of the virtual rectangle 20 divide the virtual rectangle 20 into four virtual quadrilaterals 30. Four vertices in each virtual quadrilateral 30 are respectively a first sub-pixel 11 located at a corresponding vertex corner of the virtual rectangle 20, two second sub-pixels 12 located on two adjacent sides of the virtual rectangle 20, and the first sub-pixel 11 located within the virtual rectangle 20. Further, any two opposite sides of the virtual quadrilateral 30 are not parallel.

One third sub-pixel 13 is provided in each virtual quadrilateral 30.

Specifically, in the embodiments of the present disclosure, the virtual rectangle 20 includes a first side 21, a second side 22, a third side 23, and a fourth side 24. The first side 21 is opposite to the second side 22, and the third side 23 is opposite to the fourth side 24. A line connecting the centres of the two second sub-pixels 12 respectively located on the first side 21 and the second side 22 is not parallel to the third side 23. A line connecting the centres of the two second sub-pixels 12 respectively located on the third side 23 and the fourth side 24 is not parallel to the first side 21. The centre of one first sub-pixel 11 located within the virtual rectangle 20 is on the line connecting the centres of the two second sub-pixels 12 respectively located on the first side 21 and the second side 22, and further on the line connecting the centres of the two second sub-pixels 12 respectively located on the third side 23 and the fourth side 24.

It should be noted that the second sub-pixel 12 located on the first side 21 does not contain a midpoint of the first side 21, and the second sub-pixel 12 located on the second side 22 does not contain a midpoint of the second side 22, the second sub-pixel 12 located on the third side 23 does not contain a midpoint of the third side 23, and the second sub-pixel 12 located on the fourth side 24 does not contain a midpoint of the fourth side 24.

In some embodiments of the present disclosure, the centre of the second sub-pixel 12 located on the first side 21 and the centre of the second sub-pixel 12 located on the second side 22 are respectively located on opposite sides of a mid-perpendicular line of the first side 21, the centre of the second sub-pixel 12 located on the third side 23 and the centre of the second sub-pixel 12 located on the fourth side 24 are respectively located on opposite sides of a mid-perpendicular line of the third side 23. That is, in some embodiments of the present disclosure, as shown in FIG. 1, the centre of the second sub-pixel 12 located on the first side 21 is located on the right side of the midpoint of the first side 21, and the centre of the second sub-pixel 12 located on the second side 22 is located on the left side of the midpoint of the second side 22. The centre of the second sub-pixel 12 located on the third side 23 is located above the midpoint of the third side 23, and the centre of the second sub-pixel 12 located on the fourth side 24 is located below the midpoint of the fourth side 24. The first sub-pixel 11 located within the virtual rectangle 20 is located at the centre of the virtual rectangle 20, and has a same distance to the first side 21, the second side 22, the third side 23, and the fourth side 24.

A distance from the centre of the second sub-pixel 12 located on the first side 21 to the midpoint of the first side 21 is H1, and a distance from the centre of the second sub-pixel 12 located on the second side 22 to the midpoint of the second side 22 is H2, a distance from the centre of the second sub-pixel 12 located on the third side 23 to the midpoint of the third side 23 is H3, and a distance from the centre of the second sub-pixel 12 located on the fourth side 24 to the midpoint of the fourth side 24 is H4. Optionally, the distance H1, the distance H2, the distance H3, and the distance H4 are all equal.

In some embodiments of the present disclosure, in one virtual quadrilateral 30, a line segment connecting the two first sub-pixels 11 is represented as a first virtual diagonal a, distances from the centre of the third sub-pixel 13 to the centres of the two first sub-pixels 11 are equal, and the centre of the third sub-pixel 13 is not on the first virtual diagonal a. That is, in some embodiments of the present disclosure, a position of the third sub-pixel 13 is specially designed so that the centre of the third sub-pixel 13 is not on the first virtual diagonal a of the virtual quadrilateral 30, thereby increasing the distance between the third sub-pixel 13 and the first sub-pixels 11. As the resolution of existing OLED display panels continues to improve, a distance between adjacent sub-pixels continues to shrink, while an electronic layer and a hole transfer layer in an organic functional layer are both prepared over the entire substrate, and then a leakage current may easily occur between the adjacent sub-pixels through the electronic layer, which results in an electrical crosstalk between the adjacent pixels, seriously affecting the display effect and yield rate of the OLED display panels. In some embodiments of the present disclosure, the distance between each first sub-pixel 11 and the third sub-pixel 13 in one virtual quadrilateral 30 may be increased, thereby effectively avoiding the electrical crosstalk between each first sub-pixel 11 and the third sub-pixel 13, thereby improving the display effect and yield rate of the display panel.

Furthermore, in one virtual quadrilateral 30, the third sub-pixel 13 is further located on a mid-perpendicular line of the first virtual diagonal a, ensuring that the distances from the third sub-pixel 13 to the two first sub-pixels 11 are equal to improve display uniformity.

In addition, in each virtual quadrilateral 30, a line segment connecting the two second sub-pixels 12 is represented as a second virtual diagonal b, and the centre of the third sub-pixel 13 is located at a mid-perpendicular line of the second virtual diagonal b. That is, in some embodiments of the present disclosure, the centre of the third sub-pixel 13 is located at an intersection of the mid-perpendicular line of the first virtual diagonal a and the mid-perpendicular line of the second virtual diagonal b.

In addition, in the virtual quadrilateral 30, the two sides adjacent to the first sub-pixel 11 located at the corresponding vertex corner of the virtual rectangle 20 are not equal in length, and a ratio of a short side of the two sides to a long side of the two sides ranges from 9/10 to 1 (not equal to 1), and may be 0.9, 0.91, 0.92, 0.93, 0.94, 0.95, 0.96, 0.97, 0.98, 0.99, etc, which is not limited herein.

Following the above, on at least one side of the virtual rectangle 20, a first distance from the centre of the second sub-pixel 12 to the centre of one first sub-pixel 11 adjacent to the second sub-pixel 12 is smaller than a second distance from the centre of the second sub-pixel 12 to the centre of another first sub-pixel 11 adjacent to the second sub-pixel 12. In this embodiment, each of the first side 21, the second side 22, the third side 23, and the fourth side 24 is divided into two sections with different lengths via the centre of the second sub-pixel 12 located thereon. That is, the first side 21 includes a first section and a second section, the second side 22 includes a third section and a fourth section, the third side 23 includes a fifth section and a sixth section, the fourth side 24 includes a seventh section and an eighth section. A length of the first section is greater than a length of the second section, a length of the third section is greater than a length of the fourth section, a length of the fifth section is greater than a length of the sixth section, and a length of the seventh section is greater than a length of the eighth section. For example, in FIG. 1, the first section is located on the left side of the first side 21, the second section is located on the right side of the first side 21, the third section is located on the right side of the second side 22, the fourth section is located on the left side of the second side 22, the fifth section is located on the lower side of the third side 23, the sixth section is located on the upper side of the third side 23, the seventh section is located on the upper side of the fourth side 24, and the eighth section is located on the lower side of the fourth side 24.

In some embodiments of the present disclosure, the display panel may further include a plurality of support columns 40, and each support column 40 is disposed on a corresponding side of the virtual rectangle 20 and between the adjacent first sub-pixel 11 and second sub-pixel 12. A distance from the centre of the first sub-pixel 11 adjacent to the support column 40 to the centre of the second sub-pixel 12 adjacent to the support column 40 is the second distance, that is, the support column 40 is arranged on a longer section of the side of the virtual rectangle 20. Specifically, the support columns 40 may be disposed on the first section of the first side 21, the third section of the second side 22, the fifth section of the third side 23, and the seventh section of the fourth side 24. In some embodiments of the present disclosure, the support column 40 is arranged between adjacent sub-pixels with a larger distance, which may allow an increased area of the support columns 40 and thus improve the supporting effect of the support column 40 on a mask when the mask is used for an evaporation process. This prevents the mask from scratching the display panel and improves the yield rate of the display panels.

A distance between the centre of one first sub-pixel 11 located within the virtual rectangle 20 and the second sub-pixel 12 located on the first side 21 is greater than a distance from the centre of the first sub-pixel 11 located within the virtual rectangle 20 to the first side. A distance between the centre of the first sub-pixel 11 located within the virtual rectangle 20 and the second sub-pixel 12 located on the second side 22 is greater than a distance between the centre of the first sub-pixel 11 located within the virtual rectangle 20 to the second side 22. A distance between the centre of the first sub-pixel 11 located within the virtual rectangle 20 and the second sub-pixel 12 located on the third side 23 is greater than a distance between the centre of the first sub-pixel 11 located within the virtual rectangle 20 and the third side 23. A distance between the centre of the first sub-pixel 11 located within the virtual rectangle 20 and the second sub-pixel 12 located on the fourth side 24 is greater than a distance between the centre of the first sub-pixel 11 located within the virtual rectangle 20 and the fourth side 24. That is, in some embodiments of the present disclosure, the four second sub-pixels 12 located on the four sides of the virtual rectangle 20 are specially designed. Compared to the arrangement where the sub-pixels 12 are respectively at the midpoints of the four sides of the virtual rectangle 20, the embodiment of the present disclosure may increase the distance between the first sub-pixel 11 located within the virtual rectangle 20 and any one of the four sub-pixels 11 on the four sides of the virtual rectangle 20, so as to reduce the probability of an electrical crosstalk occurring between the first sub-pixel 11 and the four second sub-pixels 12, thereby improving the display effect.

It should be noted that in any virtual quadrilateral 30, a line connecting the centre of the first sub-pixel 11 located within the virtual rectangle 20 and the centre of one adjacent second sub-pixels 12 and another line connecting the centre of the first sub-pixel 11 located within the virtual rectangle 20 and the centre of the other adjacent second sub-pixels 12 form a first angle A. A line connecting the centre of the second sub-pixel 12 on a side of the virtual rectangle 20 and the centre of one adjacent first sub-pixels 11 and another line connecting the centre of the second sub-pixel 12 on the side of the virtual rectangle 20 and the centre of the other adjacent first sub-pixels 11 form a second angle B. An absolute value of a difference between the first angle A and the second angle B is greater than 0° and less than or equal to 20°.

Further, the display panel includes a plurality of repeating units, and each repeating unit includes at least one virtual rectangle 20. That is, the display area of the display panel includes the plurality of repeating units, the sub-pixels in each repeating unit are arranged in the same manner, and the repeating units are arranged adjacent to each other to form an arrangement of multiple sub-pixels located in the display area.

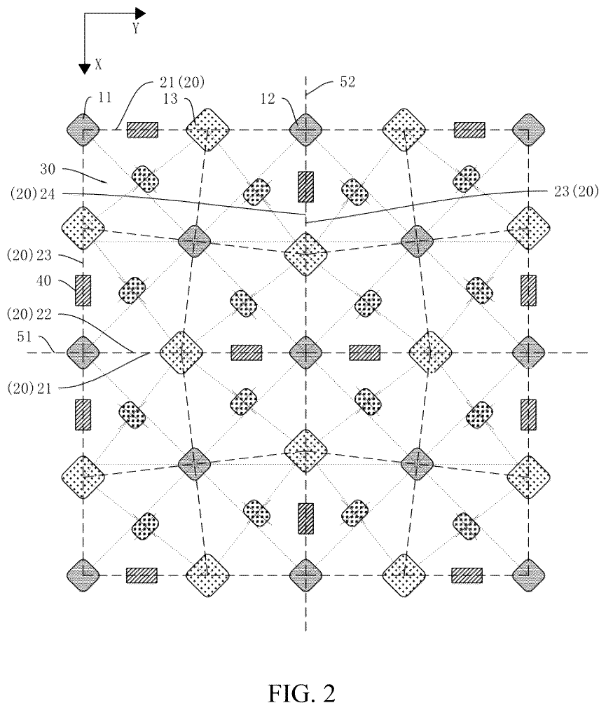

In this embodiment, each repeating unit includes four virtual rectangles 20 as shown in FIG. 1. Please refer to FIG. 1 and FIG. 2. The four virtual rectangles 20 are arranged in an array along a first direction X and a second direction Y. The first direction X is a direction pointing from the first side 21 to the second side 22, and the second direction Y is a direction pointing from the third side 23 to the fourth side 24.

In each repeating unit, in any two adjacent virtual rectangles 20 along the first direction, the first side 21 of one virtual rectangle 20 and the second side 22 of the other one virtual rectangle 20 are both on a first virtual straight line 51, and the two adjacent virtual rectangles 20 are arranged axially symmetrically with respect to the first virtual straight line 51.

Further, in each repeating unit, in any two adjacent virtual rectangles 20 along the second direction Y, the third side 23 of one virtual rectangle 20 and the fourth side 24 of the other one virtual rectangle 20 are both located on a second virtual straight line 52, the two adjacent virtual rectangles 20 are arranged axially symmetrically with respect to the second virtual straight line 52.

To sum up, the display panel provided by the embodiments of the present disclosure includes virtual rectangles 20, and each virtual rectangle 20 includes virtual quadrilaterals 30. In each virtual quadrilateral 30, the distances from the centre of the third sub-pixel 13 to the centres of the two first sub-pixels 11 are equal, and the centre of the third sub-pixel 13 is not on the line connecting the centres of the two first sub-pixels 11. That is, compared to the arrangement where the centre of the third sub-pixel 13 is on the line connecting the two first sub-pixels 11, in the present disclosure, the third sub-pixel 13 located within the virtual quadrilateral 30 is specifically designed so that the centre of the third sub-pixel 13 is not on the line connecting the centres of the two first sub-pixels 11, which may increase the distance between the third sub-pixel 13 and each first sub-pixel 11 and keep the distances between the third sub-pixel 13 and the two first sub-pixels 11 equal, thereby reducing the probability of an electrical crosstalk between the third sub-pixel 13 and the two first sub-pixels 11 and then improving the display effect. In addition, in each virtual quadrilateral 30 of the display panel, the two sides adjacent to the first sub-pixel 11 located at the vertex corner of the virtual rectangle 20 are not equal, and the longer side thereof may be used for the arrangement of the support column 40, thereby increasing the manufacturing space for the support column 40 to enhance the support effect of the support column 40 and thereby preventing any mask from scratching the display panel.

In addition, some embodiments of the present disclosure further provide a display device, the display device includes a device body and the display panel described in the above embodiments, and the display panel and the device body are combined into one body.

The device body may include at least one of a frame and a driving component, which is not limited here.

In the above embodiments, each embodiment is described with its own emphasis. For parts that are not described in detail in a certain embodiment, please refer to the relevant descriptions of other embodiments.

The above is a detailed introduction to a display panel and a display device provided by the embodiments of the present disclosure. Specific examples are used in this description to illustrate the principles and implementation methods of the present disclosure. The description of the above embodiments is only used to help understand the technical solutions and core ideas of the present disclosure. Those of ordinary skill in the art should understand that they can still modify the technical solutions recorded in the foregoing embodiments, or make equivalent substitutions for some of the technical features. However, these modifications or substitutions do not deviate the corresponding technical solution from the scope of the technical solution of the embodiments of the present disclosure.

1. A display panel, comprising a plurality of first sub-pixels, a plurality of second sub-pixels, and a plurality of third sub-pixels, wherein:
each first sub-pixel is either arranged at a corresponding one of four vertex corners of or arranged within a corresponding virtual rectangle of one or more virtual rectangles;
each second sub-pixel is arranged on a corresponding one of four sides of the virtual rectangle;
in each virtual rectangle, each first sub-pixel located at the corresponding vertex corner of the virtual rectangle, two of the plurality of second sub-pixels adjacent to the first sub-pixel, and the first sub-pixel located within the virtual rectangle form a virtual quadrilateral, such that a plurality of virtual quadrilaterals are formed in the virtual rectangle,
any two opposite sides of each virtual quadrilateral are not parallel, and
in each virtual quadrilateral, lengths of two sides of the virtual quadrilateral adjacent to the first sub-pixel located at the vertex corner of the virtual rectangle are not equal;
each third sub-pixel is disposed within a corresponding one of the plurality of virtual quadrilateral; in each virtual quadrilateral, distances between a centre of the third sub-pixel and centres of the two first sub-pixels corresponding to the virtual quadrilateral are equal, and the centre of the third sub-pixel is not on a line connecting the centres of the two first sub-pixels corresponding to the virtual quadrilateral.

2. The display panel according to claim 1, wherein in each virtual quadrilateral, the centre of the third sub-pixel is located on a mid-perpendicular line of a line connecting centres of the two second sub-pixels corresponding to the virtual quadrilateral.

3. The display panel according to claim 1, wherein on at least one side of each virtual rectangle, a first distance from a centre of the second sub-pixel to a centre of one of the first sub-pixels adjacent to the second sub-pixel is smaller than a second distance from the centre of the second sub-pixel to a centre of another of the first sub-pixels adjacent to the second sub-pixel.

4. The display panel according to claim 3, further comprising: a plurality of support columns, wherein each support column is disposed on a corresponding side of the virtual rectangle and is between one of the plurality of first sub-pixels and one of the plurality of second sub-pixels that are on the side of the virtual rectangle and adjacent to each other, and a distance from a centre of the first sub-pixel adjacent to the support column to a centre of the second sub-pixel adjacent to the support column is the second distance.

5. The display panel according to claim 1, wherein each virtual rectangle comprises a first side, a second side, a third side, and a fourth side, the first side is arranged opposite to the second side, and the third side is arranged opposite to the fourth side;
a line connecting centres of two of the plurality of second sub-pixels respectively located on the first side and the second side is not parallel to the third side; and
a line connecting centres of other two of the plurality of second sub-pixels respectively located on the third side and the fourth side is not parallel to the first side.

6. The display panel according to claim 5, wherein in the virtual rectangle, a centre of one of the second sub-pixel located on the first side does not overlap with a midpoint of the first side, a centre of the second sub-pixel located on the second side does not overlap with a midpoint of the second side, a centre of the second sub-pixel located on the third side does not overlap with a midpoint of the third side, and a centre of the second sub-pixel located on the fourth side does not overlap with a midpoint of the fourth side.

7. The display panel according to claim 6, wherein in the virtual rectangle, the centre of the second sub-pixel located on the first side and the centre of the second sub-pixel located on the second side are respectively located on opposite sides of a mid-perpendicular line of the first side, and
the centre of the second sub-pixel located on the third side and the centre of the second sub-pixel located on the fourth side are respectively located on opposite sides of a mid-perpendicular line of the third side.

8. The display panel according to claim 7, wherein in the virtual rectangle, a distance from the centre of the second sub-pixel located on the first side to the midpoint of the first side, a distance from the centre of the second sub-pixel located on the second side to the midpoint of the second side, a distance from the centre of the second sub-pixel located on the third side to the midpoint of the third side, and a distance from the centre of the second sub-pixel located on the fourth side to the midpoint of the fourth side are equal.

9. The display panel according to claim 5, wherein in the virtual rectangle, a distance from a centre of the first sub-pixel within the virtual rectangle to the first side, a distance from the centre of the first sub-pixel within the virtual rectangle to the second side, a distance from the centre of the first sub-pixel within the virtual rectangle to the third side, and a distance from the centre of the first sub-pixel within the virtual rectangle to the fourth side are equal.

10. The display panel according to claim 5, comprising a plurality of repeating units, wherein each repeating unit comprises four virtual rectangles, and the four virtual rectangles are arranged in an array along a first direction and a second direction, the first direction is a direction pointing from the first side to the second side, and the second direction is a direction pointing from the third side to the fourth side;
in each repeating unit, in any two adjacent virtual rectangles along the first direction, the first side of one of the two virtual rectangles and the second side of the other of the two virtual rectangles are both on a first virtual straight line, and the two virtual rectangles are arranged axially symmetrically with respect to the first virtual straight line; and
in each repeating unit, in any two adjacent virtual rectangles along the second direction, the third side of one of the two virtual rectangles and the fourth side of the other of the two virtual rectangles are both located on a second virtual straight line, and the two virtual rectangles are arranged axially symmetrically with respect to the second virtual straight line.

11. The display panel of claim 1, wherein in each virtual rectangle, lines connecting a centre of the first sub-pixel located within the virtual rectangle and centres of four of the plurality of second sub-pixels respectively located on the four sides of the virtual rectangle divide the virtual rectangle into four virtual quadrilaterals.

12. The display panel according to claim 11, wherein in any one of the virtual quadrilaterals, the first sub-pixel located within the virtual rectangle is adjacent to two of the plurality of second sub-pixels corresponding to the virtual quadrilateral, a line connecting the centre of the first sub-pixel located within the virtual rectangle and a centre of one of the two adjacent second sub-pixels and another line connecting the centre of the first sub-pixel located within the virtual rectangle and a centre of the other one of the two adjacent second sub-pixels form a first angle,
the second sub-pixel on a side of the virtual rectangle is adjacent to two of the plurality of first sub-pixels, a line connecting a centre of the second sub-pixel on the side of the virtual rectangle and a centre of one of the two adjacent first sub-pixels and another line connecting the centre of the second sub-pixel on the side of the virtual rectangle and a centre of the other one of the two adjacent first sub-pixels form a second angle, and
an absolute value of a difference between the first angle and the second angle is greater than 0° and less than or equal to 20°.

13. A display device, wherein the display device comprises a device body and a display panel, and the display panel and the device body are combined into one body,
the display panel comprises a plurality of first sub-pixels, a plurality of second sub-pixels, and a plurality of third sub-pixels, wherein:
each first sub-pixel is either arranged at a corresponding one of four vertex corners of or arranged within a corresponding virtual rectangle of one or more virtual rectangles;
each second sub-pixel is arranged on a corresponding one of four sides of the virtual rectangle;
in each virtual rectangle, each first sub-pixel located at the corresponding vertex corner of the virtual rectangle, two of the plurality of second sub-pixels adjacent to the first sub-pixel, and the first sub-pixel located within the virtual rectangle form a virtual quadrilateral, such that a plurality of virtual quadrilaterals are formed in the virtual rectangle,
any two opposite sides of each virtual quadrilateral are not parallel, and
in each virtual quadrilateral, lengths of two sides of the virtual quadrilateral adjacent to the first sub-pixel located at the vertex corner of the virtual rectangle are not equal;
each third sub-pixel is disposed within a corresponding one of the plurality of virtual quadrilateral; in each virtual quadrilateral, distances between a centre of the third sub-pixel and centres of the two first sub-pixels corresponding to the virtual quadrilateral are equal, and the centre of the third sub-pixel is not on a line connecting the centres of the two first sub-pixels corresponding to the virtual quadrilateral.

14. The display device according to claim 13, wherein in each virtual quadrilateral, the centre of the third sub-pixel is located on a mid-perpendicular line of a line connecting centres of the two second sub-pixels corresponding to the virtual quadrilateral.

15. The display device according to claim 13, wherein on at least one side of each virtual rectangle, a first distance from a centre of the second sub-pixel to a centre of one of the first sub-pixels adjacent to the second sub-pixel is smaller than a second distance from the centre of the second sub-pixel to a centre of another of the first sub-pixels adjacent to the second sub-pixel.

16. The display device according to claim 15, wherein the display panel further comprises: a plurality of support columns, wherein each support column is disposed on a corresponding side of the virtual rectangle and is between one of the plurality of first sub-pixels and one of the plurality of second sub-pixels that are on the side of the virtual rectangle and adjacent to each other, and a distance from a centre of the first sub-pixel adjacent to the support column to a centre of the second sub-pixel adjacent to the support column is the second distance.

17. The display device according to claim 13, wherein each virtual rectangle comprises a first side, a second side, a third side, and a fourth side, the first side is arranged opposite to the second side, and the third side is arranged opposite to the fourth side;
a line connecting centres of two of the plurality of second sub-pixels respectively located on the first side and the second side is not parallel to the third side; and
a line connecting centres of other two of the plurality of second sub-pixels respectively located on the third side and the fourth side is not parallel to the first side.

18. The display device according to claim 17, wherein in the virtual rectangle, a centre of one of the second sub-pixel located on the first side does not overlap with a midpoint of the first side, a centre of the second sub-pixel located on the second side does not overlap with a midpoint of the second side, a centre of the second sub-pixel located on the third side does not overlap with a midpoint of the third side, and a centre of the second sub-pixel located on the fourth side does not overlap with a midpoint of the fourth side.

19. The display device according to claim 18, wherein in the virtual rectangle, the centre of the second sub-pixel located on the first side and the centre of the second sub-pixel located on the second side are respectively located on opposite sides of a mid-perpendicular line of the first side, and
the centre of the second sub-pixel located on the third side and the centre of the second sub-pixel located on the fourth side are respectively located on opposite sides of a mid-perpendicular line of the third side.

20. The display device according to claim 19, wherein in the virtual rectangle, a distance from the centre of the second sub-pixel located on the first side to the midpoint of the first side, a distance from the centre of the second sub-pixel located on the second side to the midpoint of the second side, a distance from the centre of the second sub-pixel located on the third side to the midpoint of the third side, and a distance from the centre of the second sub-pixel located on the fourth side to the midpoint of the fourth side are equal.
